(19) United States
(12) Patent Application Publication
(10) Pub. No.: US 2013/0314095 A1
(43) Pub. Date: Nov. 28, 2013

(54) BATTERY DEGRADATION DETERMINING DEVICE

(71) Applicant: Sanyo Electric Co., Ltd., Osaka (JP)

(72) Inventors: Takeshi Nakashima, Osaka (JP); Chie Sugigaki, Osaka (JP); Yasuo Okuda, Osaka (JP)

(73) Assignee: Sanyo Electric Co., Ltd., Osaka (JP)

(21) Appl. No.: 13/951,782

(22) Filed: Jul. 26, 2013

Related U.S. Application Data
(63) Continuation of application No. PCT/JP2012/066237, filed on Jun. 26, 2012.

(30) Foreign Application Priority Data
Jun. 29, 2011 (JP) 2011-143810

(51) Int. Cl. G01R 31/36

(52) U.S. Cl. CPC G01R 31/3606; G01R 31/362
USPC 324/433; 324/434

(57) ABSTRACT

A battery block 12 includes a parallel or series circuit of battery units. Each battery unit is provided with a battery module including at least one secondary battery. Measured voltage values VDET[1]˜VDET[n] and measured current values IDET[1]˜IDET[n]) from the battery modules 1[1]˜1[n] inside the battery units BU[1]˜BU[n] are sent to a main control unit 11. When battery modules 1[1] and 1[2] are connected in parallel, the difference between IDET[1] and IDET[2] is equal to or greater than a predetermined value, and IDET[1]>IDET[2], it is determined that the degraded state of battery module 1[2] has reached a specific state. When the difference between IDET[1] and IDET[2] is equal to or greater than the predetermined value, and IDET[1]<IDET[2], it is determined that the degraded state of battery module 1[1] has reached a specific state.

### CROSS-REFERENCE TO RELATED APPLICATIONS

This is a continuation of International Application PCT/JP2012/066237, with an international filing date of Jun. 26, 2012, filed by applicant, the disclosure of which is hereby incorporated by reference in its entirety.

### FIELD OF THE INVENTION

The present invention relates to a battery degradation determining device which determines the degraded state (whether or not there has been degradation) of the battery module of a secondary battery.

### BACKGROUND

In order to increase the capacity and output voltage, a plurality of battery modules including secondary batteries have been incorporated into systems or devices (see Patent Document 1 below). At this time, there is a desire to develop dedicated battery modules (battery packs) for each system, and to utilize standardized battery modules in series or in parallel. However, batteries in battery modules connected in series or in parallel sometimes experience significant degradation for whatever reason. As a result, when a plurality of battery modules is connected in parallel, there is a degree in the level of current flowing to the battery module that has experienced significant degradation. When charged at a predetermined current value, significantly greater current flows to the other battery modules, and this promotes further degradation. When a plurality of battery modules is connected in series, the charging current flowing to the battery modules is the same, but the storage capacity of the battery module that has experienced significant degradation is lower, and the battery module quickly reaches the fully charged state.

When a plurality of battery modules connected in parallel is discharged, the level of current flowing from the battery module (battery pack) that has experienced significant degradation is lower. When discharged at a predetermined current, more current flows from the other battery modules (battery packs) and this promotes further degradation. When a plurality of battery modules connected in series is discharged, the same current flows from each battery module. However, because the capacity of the degraded battery module is low, this battery module more quickly reaches the fully discharged state. The other battery modules connected in series still have significant discharge capacity, but further discharge causes the degraded battery module to reach an over-discharged state.

### CITED DOCUMENTS

### Patent Documents

Patent Document 1: Laid-Open Patent Publication No. 8-138759A

### SUMMARY

### Problem Solved by the Invention

When a significantly degraded battery module is included among a plurality of battery modules connected in series or in parallel as explained above, charging has to be stopped before the charge capacity of the other battery modules is reached in order to avoid over-charging the degraded battery module, and discharging has to be stopped before the discharge capacity of the other battery modules is reached in order to avoid over-discharging the degraded battery module. Therefore, when there are significantly degraded battery modules in a system incorporating a plurality of battery modules, overall system performance may be impeded. As a result, degraded battery modules have to be detected.

An object of the present invention is to provide a battery degradation determining device capable of determining whether or not a battery module has degraded during normal operation.

### Means of Solving the Problem

A first aspect of the present invention is a battery degradation determining device for a plurality of battery modules each having one or more secondary batteries, the battery degradation determining device characterized in that: the plurality of battery modules are connected in parallel to each other; and the battery degradation determining device determines whether or not each battery module has degraded by comparing the charge or discharge current values of the plurality of battery modules.

A second aspect of the present invention is a battery degradation determining device for a plurality of battery modules each having one or more secondary batteries, the battery degradation determining device characterized in that: the plurality of battery modules are connected in series to each other; and the battery degradation determining device determines whether or not each battery module has degraded by comparing the rate of change in the output voltage of the plurality of battery modules when the battery modules are charged or discharged.

### Effect of the Invention

The present invention is able to provide a battery degradation determining device capable of determining whether or not a battery module has degraded during normal operation.

### BRIEF DESCRIPTION OF THE DRAWINGS

FIG. 1 is an internal configuration diagram of the battery unit in an embodiment of the present invention.

FIG. 2 is an overall configuration diagram of the battery system in an embodiment of the present invention.

FIG. 3 is an internal configuration diagram of the battery unit in another embodiment of the present invention.

FIG. 4 is a diagram showing the battery degradation state determining unit in the main control unit of FIG. 2.

FIG. 5 is a diagram showing two battery units connected in parallel.

FIG. 6 is a diagram showing three battery units connected in parallel.

FIG. 7 is a diagram showing the relationship between the assumed current values in the fifth example of the present invention.

FIG. 8 is a diagram showing two battery units connected in series.

FIG. 9 is a diagram showing three battery units connected in series.

FIG. 10 is a diagram showing the relationship between the assumed rate-of-change values in the tenth example of the present invention.

### DETAILED DESCRIPTION

The following is a detailed explanation of examples of embodiments of the present invention. In each referenced drawing, identical components are denoted by the same reference symbols. As a general rule, redundant explanation of the same components has been eliminated. For the sake of simplicity, signs or symbols may be used with reference to information, physical quantities, states or members, and the names of the information, physical quantities, states or members referred to by the signs or symbols may be abbreviated or eliminated altogether.

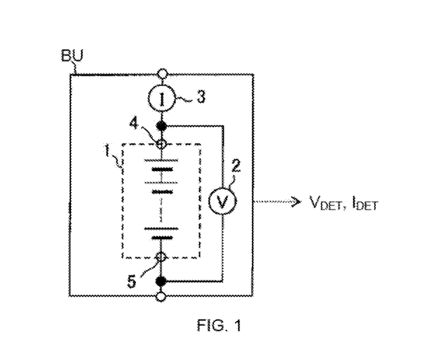

FIG. 1 is an internal configuration diagram of the battery unit BU in an embodiment of the present invention. This battery unit BU is equipped with a battery module 1 having one or more secondary batteries. The secondary batteries forming the battery module 1 can be any type of secondary battery, such as lithium ion batteries and nickel-hydrogen batteries. A single secondary battery may form the battery module 1. However, in the present embodiment, the battery module 1 includes a plurality of secondary batteries connected in series. Some or all of the secondary batteries in the battery module 1 may also be secondary batteries connected in parallel. Among the secondary batteries connected in parallel in the battery module 1, the positive electrode of the secondary battery located on the higher potential side is connected to the positive terminal 4, and the negative electrode of the secondary battery located on the lower potential side is connected to the negative terminal 5. The positive terminal 4 and the negative terminal 5 are connected to a single pair of output terminals on the battery unit BU, and the battery module 1 is charged and discharged via this single pair of output terminals.

A voltage measuring device 2 and a current measuring device 3 are also provided in the battery unit BU. The voltage measuring device 2 measures the output voltage of the battery module 1, that is, the voltage between the positive terminal 4 and the negative terminal 5 with respect to the potential of the negative terminal 5. The value of the output voltage of the secondary battery 1 measured by the voltage measuring device 2 is represented by the symbol VDET. The current measuring device 3 measures the current flowing through the positive terminal 4. The value of the current measured by the current measuring device 3 is represented by the symbol IDET. The current flowing through the positive terminal 4 is classified as the charging voltage or discharge voltage of the battery module 1 depending on the direction. The polarity of the current measurement value IDET is different, depending on whether the current flowing through the positive terminal 4 is discharge voltage or charging voltage. The voltage measuring device 2 and the current measuring device 3 can also be provided on the outside of the battery unit BU. In the present embodiment, charge and discharge refer to the battery module 1 unless otherwise indicated.

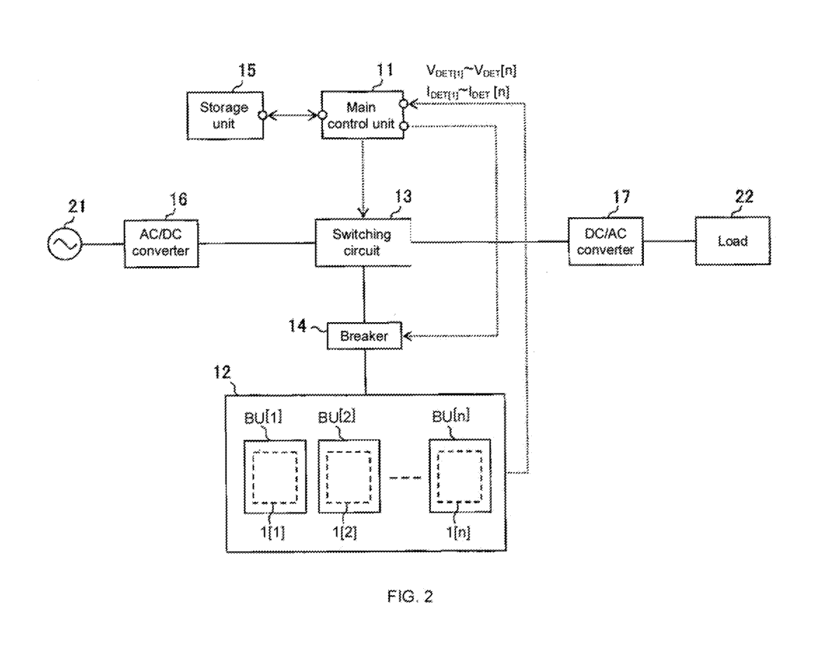

FIG. 2 is an overall configuration diagram of the battery system in an embodiment of the present invention. A battery system can be formed to include some or all of the portions shown in FIG. 2. For example, the battery system can include each section referred to by symbols 11˜13, and some or all of the sections referred to by symbols 14˜17.

The main control unit 11 includes a microcomputer, and has charge/discharge control of the battery block 12, switching control of the switching circuit 13, and operational control of the breaker 14.

The battery block 12 has n battery units BU. Here, n is an integer equal to or greater than 2. The n battery units BU in the battery block 12 are represented by the symbols BU[1]˜BU[n]. The internal configuration of the battery units BU[1]˜BU[n] can differ from one another, but in the present embodiment, the battery block has battery units BU[1]˜BU[n] which are all the same. (Thus, the n battery modules 1 in the battery units BU[1]˜BU[n] all have the same configuration.) Some or all of the battery units BU[1]˜BU[n] are connected in parallel or in series.

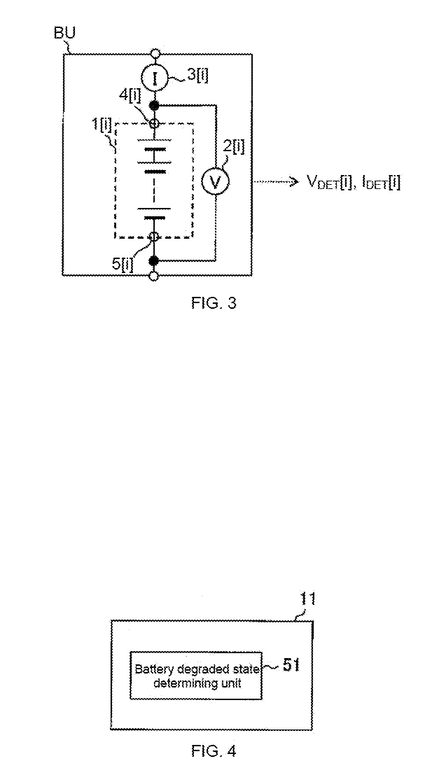

As shown in FIG. 3, the battery module 1, voltage measuring device 2, current measuring device 3, positive terminal 4, and negative terminal 5 of each battery unit BU [i] are denoted by the symbols 1[i], 2[i], 3[i], 4[i] and 5[i], and the voltage measurement values VDET of the voltage measuring device 2[i] and the current measurement values IDET of the current measuring device 3[i] are denoted by the symbols VDET[i] and IDET[i] (where i is an integer). The voltage measurement values VDET[1]˜VDET[n] and the current measurement values DET[1]˜IDET[n] are transmitted from the battery units BU[1]˜BU[n] to the main control unit 11.

The switching circuit 13 is a switching element, which is controlled by the main control unit 11 to connect or disconnect the AC/DC converter 16 and the battery block 12, to connect or disconnect the AC/DC converter 16 and the DC/AC converter 17, and to connect and disconnect the battery block 12 and the DC/AC converter 17. The switching circuit 13 can be controlled by the main control unit 11 to connect the AC/DC converter 16 and battery block 12 to charge each battery module 1 of the battery units BU[1]˜BU[n] using the voltage outputted from the AC/DC converter 16, and to connect the battery block 12 to the DC/AC converter 17 to discharge each battery module 1 of the battery units BU[1]˜BU[n].

The breaker 14 is a mechanical relay interposed in series between the battery block 12 and the switching circuit 13 to break the connection if necessary between the battery block 12 and the switching circuit 13. In this explanation, unless otherwise indicated, the connection between the battery block 12 and the switching circuit 13 is maintained. The storage unit 15 is memory such as semiconductor memory or a magnetic disk. The main control unit 11 can store any information in the storage unit 15, and can read any information stored in the storage unit 15 on any timing. The storage unit 15 may be connected to the main control unit 11 via a communication network such as the internet.

The alternating current power source 21 is, for example, a commercial alternating current power source, and outputs alternating current power at a predetermined frequency and voltage value. The AC/DC converter 16 converts the alternating current from the alternating current power source 21 to direct current power, and outputs the direct current power. Depending on the connection state of the switching element in the switching circuit 13, direct current power outputted from the AC/DC converter 16 and/or direct current power discharged from the battery block 12 is supplied to the DC/AC converter 17. The DC/AC converter 17 converts the supplied direct current power to alternating current power, and supplies the alternating current power to the load 22.

Instead of a DC/AC converter 17 and load 22 or in addition to a DC/AC converter 17 and load 22, a direct current load (not shown) operated by direct current power can be connected to the switching circuit 13, and the direct current load can be operated using power discharged from each battery module 1. Also, in addition to an alternating current power source 21 and AC/DC converter 16 or in addition to an alternating current power source 21 and AC/DC converter 16, a direct current power source (for example, a solar cell; not shown) which outputs direct current power can be connected to the switching circuit 13, and each battery module 1 can be charged using the direct current power source outputted by the direct current power source.

As shown in FIG. 4, the main control unit 11 includes a battery degradation state determining unit (battery degradation determining device) 51 for determining the degradation state of each battery module 1 in the battery units BU[1]˜BU[n]. The following is an explanation of the first through tenth examples, which are all examples related to degradation determination. Unless they are inconsistent with each other, elements described in the first through tenth examples can be applied to other embodiments of the present invention.

### 1st Example

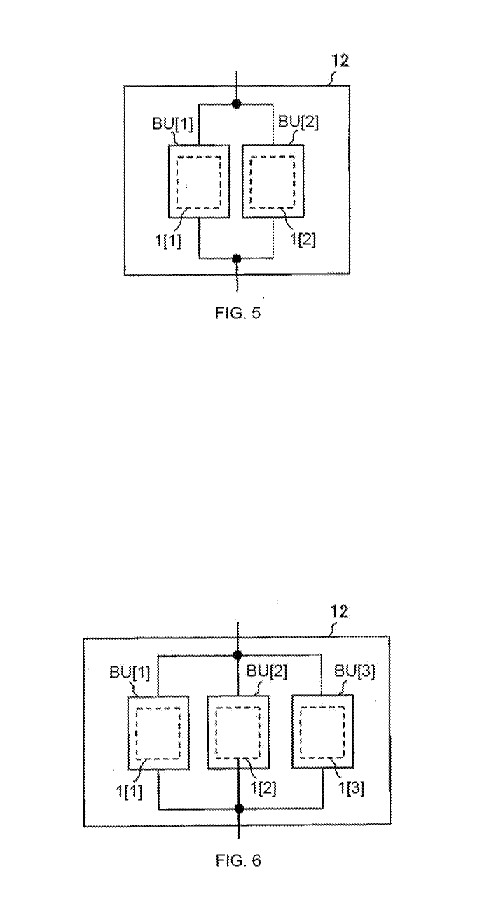

The following is an explanation of the first example. In the first example, as shown in FIG. 5, battery units BU[1] and BU[2] among battery units BU[1]˜BU[n] are connected to each other in parallel. As a result, battery module 1[1] and battery module 1[2] are assumed to be connected to each other in parallel.

Because battery modules 1[1] and 1[2] are connected in parallel, the output voltage of battery modules 1[1] and 1[2] is the same. If battery modules 1[1] and 1[2] have the same characteristics (including degradation state), charge current or discharge current with the same current value flows to both battery modules 1[1] and 1[2]. However, when one or the other of the battery modules 1[1] and 1[2] degrades, the internal resistance in the battery module with the greater degree of degradation will be greater, and the difference in current values between the battery modules 1[1] and 1[2] becomes too large to ignore.

Therefore, the battery degraded state determining unit 51 (referred to simply as the determining unit 51 below) compares the measured current value IDET[1] indicating the charge or discharge current value of the battery module 1[1] to the measured current value IDET[2] indicating the charge or discharge current value of the battery module 1[2] in order to determine the degradation states of battery modules 1[1] and 1[2]. The current values IDET[1] and IDET[2] to be compared are, of course, current values measured on the same timing. For the sake of convenience, the polarity of the measured current value IDET[i] in the first example and all other examples described below is positive. In the case of IDET[i], only the magnitude of the charge or discharge current value of battery module 1[i] will be considered.

More specifically, the determining unit 51 performs a specific degradation determination on either battery module 1[1] or 1[2] when Equation (A1) described below is satisfied, and performs a specific degradation determination on neither battery module 1[1] nor 1[2] when Equation (A1) is not satisfied. When the determining unit 51 performs the specific degradation determination on either battery module 1[1] or 1[2], the specific degradation determination is performed on battery module 1[2] if unequal equation “IDET[1]>IDET[2]” is satisfied, and the specific degradation determination is performed on battery module 1[1] if unequal equation “IDET[1]<IDET[2]” is satisfied. In Equation (A1) and Equations (A2), (A3) and (A4) described below, the unequal sign can be “>” rather than “≧”.

|IDET[1]−IDET[2]|≧THA (A1)

THA is a specific current value with a positive value. The current value THA can be a predetermined fixed value, or can be a variable that changes depending on the SOC, measured voltage value VDET, or temperature of the battery module 1. The SOC (state of charge) of battery module 1[i] is the percentage of actual remaining capacity in the battery module 1 relative to the storage capacity of battery module 1[i] when battery module 1[i] is fully charged.

A specific degradation determination for battery module 1[i] indicates that the degradation state of battery module 1[i] has reached a specific state (for example, the state at which the battery module 1[i] has to be replaced). Therefore, when a specific degradation determination is not performed on battery module 1[i], it means the degradation state of the battery module 1[i] has not reached the specific state. When the specific degradation determination has been performed on battery module 1[i], the determining unit 51 outputs a degradation signal related to battery module 1[i]. (The same is true in the other examples described below.) The degradation signal related to battery module 1[i] indicates whether the degradation state of the battery module 1[i] has reached the specific state. In other words, this signal indicates whether battery module 1[i] currently incorporated in the battery system should be replaced with another battery module 1 (new battery module 1). The user or manager of the battery system can realize that a degradation signal has been outputted via video or audio output, or light emitted by a diode corresponding to the output of a degradation signal. The output of degradation signals can be used to properly determine when each battery module 1 needs to be replaced by another battery module 1.

In this example, by introducing a simple comparison process, the degraded state of a battery module can be easily determined during normal operation of the battery system in which the battery module 1 is charging or discharging electricity.

In the first example, IDET[1] and IDET[2] correspond to first and second comparison amounts. When the difference between the first and second comparison amounts is greater than a predetermined level, the determining unit 51 performs a specific degradation determination on either battery module 1[1] or battery module 1[2]. When the difference between the first and second comparison amounts is less than a predetermined level, the determining unit 51 performs a specific degradation determination on neither battery module 1[1] nor battery module 1[2]. The size relationship between the difference in the first and second comparison amounts and the predetermined level may be evaluated using a ratio of the first and second comparison amounts. (The same is true in the second through fifth examples described below.) When the ratio of the first and second comparison amounts falls outside of a predetermined numerical range, the difference between the first and second comparison amounts is greater than the predetermined level. When the ratio of the first to second comparison amounts is within the predetermined numerical range, the difference between the first and second comparison amounts is less than the predetermined level. (The same is true in the second through fifth examples described below.) The numerical range is the numerical range from predetermined threshold value THU to predetermined threshold value THL, where THU>1>THL>0. If the larger of the two physical amounts corresponding to the first and second comparison amounts (IDET[1] and IDET[2] in the first example) is the first comparison amount, the ratio of the first comparison amount to the second comparison amount (that is, 1st comparison amount/2nd comparison amount) is compared to threshold value THU. When the ratio is greater than THU, a specific degradation determination is performed on the battery module corresponding to the second comparison amount.

### 2nd Example

The following is an explanation of the second example. In the second example, as shown in FIG. 6, battery units BU[1] and BU[3] among battery units BU[1]˜BU[n] are connected to each other in parallel. As a result, battery module 1[1] through battery module 1[3] are assumed to be connected to each other in parallel. When three battery modules 1 are connected in parallel, the degradation state can be determined using the method described in the first example.

In other words, by comparing measured current values IDET[1]˜IDET[3], the determining unit 51 determines the degradation state of battery modules 1[1]˜1[3]. Of course, the current values IDET[1]˜IDET[3] to be compared are measured on the same timing.

More specifically, the determining unit 51 first extracts the maximum current value and a non-maximum current value, or current value other than the maximum current value, from the current values IDET[1]˜IDET[3]. Here, the maximum current value is represented by the symbol IDET[MAX], and the two non-maximum current values are represented by the symbols IDET[NOTMAX1] and IDET[NOTMAX2].

The determining unit 51 treats current values IDET[MAX] and IDET[NOTMAX1] as IDET[1] and IDET[2] in the first example, and performs the same determination process as that in the first example. It also treats current values IDET[MAX] and IDET[NOTMAX2] as IDET[1] and IDET[2] in the first example, and performs the same determination process as that in the first example. In other words, the determining unit 51 performs a specific degradation determination on the battery module 1 corresponding to current value IDET[NOTMAX1] when Equation (A2) below is satisfied, and does not perform the specific degradation determination on the battery module 1 corresponding to current value IDET[NOTMAX1] when Equation (A2) below is not satisfied. Similarly, the determining unit 51 performs a specific degradation determination on the battery module 1 corresponding to current value IDET[NOTMAX2] when Equation (A3) below is satisfied, and does not perform the specific degradation determination on the battery module 1 corresponding to current value IDET[NOTMAX2] when Equation (A3) below is not satisfied. When current value IDET[NOTMAX1] is current value IDET[i], the battery module 1 corresponding to current value IDET[NOTMAX1] is battery module [i]. (The same is true of current values IDET[MAX] and IDET[NOTMAX2]).

IDET[MAX]−IDET[NOTMAX1]|≧THA (A2)

IDET[MAX]−IDET[NOTMAX2]|≧THA (A3)

The determining unit 51 does not perform the specific degradation determination on the battery module corresponding to current value IDET[MAX], regardless of whether Equations (A2) and (A3) are satisfied. The battery module 1 corresponding to current value IDET[MAX] has the lowest internal resistance value of battery modules 1[1]˜1[3] and is thus considered to have the lowest degree of degradation.

Results similar to those in the first example are obtained in the second example. In the second example, the degradation state of another battery module 1 can be determined on the assumption that the battery module 1 corresponding to current value IDET[MAX] is a battery module with no degradation or a very low level of degradation.

In the second example, IDET[MAX] and IDET[NOTMAX1] correspond to the first and second comparison amounts, and IDET[MAX] and IDET[NOTMAX2] also correspond to the first and second comparison amounts. When the difference between the first and second comparison amounts is greater than a predetermined level, the determining unit 51 performs a specific degradation determination on the battery module 1 corresponding to IDET[NOTMAX1] or IDET[NOTMAX2]. When the difference between the first and second comparison amounts is less than a predetermined level, the determining unit 51 does not perform a specific degradation determination on the battery module 1 corresponding to IDET[NOTMAX1] or IDET[NOTMAX2]. As in the first example, the size relationship between the difference in the first and second comparison amounts and the predetermined level is evaluated using the ratio of the first and second comparison amounts.

In the second example, the degradation state determining process was performed on three battery modules 1 connected in parallel. However, the same process can also be performed when four or more battery modules 1 are connected in parallel.

### 3rd Example

The following is an explanation of the third example. In the second example, a non-maximum current value was compared to a reference current value, the reference current value being the extracted maximum current value. However, the reference current value compared to the non-maximum current value can be generated from a plurality of measured current values including the maximum current value.

The following is a specific example. Here, battery units BU[1]˜BU[m] among battery units BU[1]˜BU[n] are connected in parallel. Therefore, it is assumed that battery modules 1[1]˜1[m] are also connected in parallel. Here, m is any integer less than n and equal to or greater than 3. In this explanation, m=4.

The determining unit 51 determines the degraded state of each battery module by comparing current values IDET[1]˜IDET[4] measured on the same timing. At this time, the measured current values IDET[1]˜IDET[4] are classified as being in a first group or a second group. The current values classified as being in the first group (that is, the current values belonging to the first group) are all greater than the current values classified as being in the second groups (that is, current values belonging to the second group). Therefore, the maximum current value among measured current values IDET[1]˜IDET[4] is classified as being in the first group. More specifically, the measured current values whose difference with respect to the maximum current value among measured current values IDET[1]˜IDET[4] is less than a predetermined positive value are extracted and classified as being in the first group. The rest of the measured current values are classified as being in the second group.

The determining unit establishes the reference current value IDET[MAX′] using the measured current values belonging to the first group. When the only measured current value belonging to the first group is the maximum current value itself, the maximum current value is used as reference current value IDET[MAX′]. When there is more than one measured current value belonging to the first group, the average value of the measured current values belonging to the first group is used as the reference current value IDET[MAX]. After the reference current value IDET[MAX′] has been established, the determining unit 51 treats IDET[MAX′] in the same way as IDET[MAX] in the second example, and performs the determination process in the same manner as the second example.

For example, when measured current values IDET[1] and IDET[2] belong to the first group and measured current values IDET[3] and IDET[4] belong to the second group, the determining unit 51 uses IDET[1] and IDET[2] to establish IDET[MAX′], treats IDET[3] and IDET[4] as IDET[NOTMAX1] and IDET[NOTMAX2], and performs the process in the same manner as the second example using IDET[MAX′] as IDET[MAX] from the second example. As in the case of the first group, a single current value may belong to the second group.

The specific degradation determination is not performed on a battery module 1 corresponding to a measured current value belonging to the first group. This is because any battery module 1 in the first group is assumed to have a relatively low degree of degradation. The results in the third example are similar to those in the first example. In the third example, the degradation state of other battery modules 1 can be determined on the assumption that the battery modules 1 in the first group are reference battery modules 1 with either no degradation or very little degradation.

### 4th Example

The following is an explanation of the fourth example. Here, battery units BU[1]˜BU[m] among battery units BU[1]˜BU[n] are connected in parallel. Therefore, it is assumed that battery modules 1[1]˜1[m] are also connected in parallel. (Here, m is an integer equal to or greater than 3.)

In this example, the determining unit 51 determines the degradation state of each combination of two battery modules 1[i] and 1[j] among the battery modules 1[1]˜1[m]. Here, i and j in battery modules 1[i] and 1[j] are different integers.

In this particular example, m=3. First, the determining unit 51 establishes the combination of battery modules 1[1] and 1[2] as the combination whose degradation states are to be determined, and determines the degradation states of the battery modules 1[1] and 1[2] by comparing the measured current values IDET[1] and IDET[2]. This method of determination matches the one in the first example. Second, the determining unit 51 establishes the combination of battery modules 1[2] and 1[3] as the combination whose degradation states are to be determined, and determines the degradation states of the battery modules 1[2] and 1[3] by comparing the measured current values IDET[2] and IDET[3]. This method of determination is also the same as the one in the first example (except that 1[1], 1[2], IDET[1] and IDET[2] in the first example are replaced by 1[2], 1[3], IDET[2] and IDET[3]). Third, the determining unit 51 establishes the combination of battery modules 1[3] and 1[1] as the combination whose degradation states are to be determined, and determines the degradation states of the battery modules 1[3] and 1[1] by comparing the measured current values IDET[3] and IDET[1]. This method of determination is also the same as the one in the first example (except that 1[1], 1[2], IDET[1] and IDET[2] in the first example are replaced by 1[3], 1[1], IDET[3] and IDET[1]).

In the fourth example, the degradation state determination is performed on combinations of two battery modules using a comparison of current values. Here, the maximum current value does not have to be explicitly extracted. The operations and effects of the second example can be obtained by comparing the measured current values in any combination as the maximum current value and non-maximum current value. However, when a large number of battery modules 1 are connected in parallel, establishing a reference current value (IDET[MAX] or IDET[MAX′]) as in the second or third example is preferred as it reduces the computational load.

### 5th Example

The following is an explanation of the fifth example. Here, battery units BU[1]˜BU[m] among battery units BU[1]˜BU[n] are connected in parallel. Therefore, it is assumed that battery modules 1[1]˜1[m] are also connected in parallel. Here, m is any integer less than n and equal to or greater than 3. In this explanation, m=9.

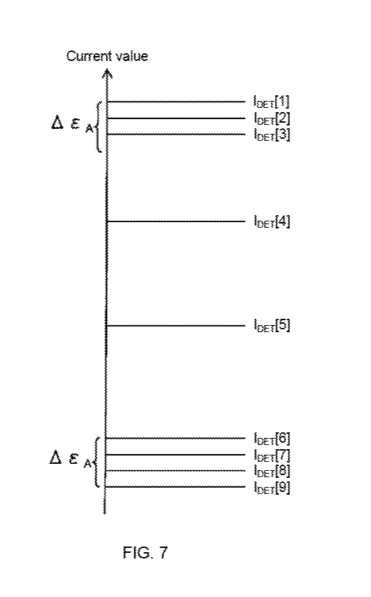

The determining unit 51 classifies current values IDET[1]˜IDET[9] measured on the same timing into a plurality of groups. At this time, the determining unit 51 classifies the current values IDET[1]˜IDET[9] so that current values within the same range of a predetermined size ΔεA are within the same group (ΔεA>0). Here, it is assumed, as shown in FIG. 7, that inequality equation “IDET[1]>IDET[2]>IDET[3]>IDET[4]>IDET[5]>IDET[6]>IDET[7]>IDET[8]>IDET[9]” has been established, and that that inequality equations “IDET[1]−IDET[3]<ΔεA”, “IDET[1]−IDET[4]>ΔεA”, “IDET[4]−IDET[5]>ΔεA”, “IDET[5]-IDET[6]>ΔεA” and “IDET[6]−IDET[9]<ΔεA” have also been established. Also, for any integer i, the current values belonging to the ith group are greater than the current values belonging to the (i+1)th group. Therefore, current values IDET[1]˜IDET[3] are classified as being in the 1st group, current value IDET[4] is classified as being in the 2nd group, current value IDET[5] is classified as being in the 3rd group, and current values IDET[6]˜IDET[9] are classified as being in the 4th group.

After classifying the current values in the first through fourth groups, the determining unit 51 establishes representative values (statistical amounts) for each group. When a group includes only a single value, the representative value is the current value belonging to the group. Therefore, the representative values for the second and third groups are, respectively, current values IDET[4] and IDET[5]. When there are two or more current values in a single group, the representative value for the group can be the average value, median value, maximum value or minimum value of the two or more current values belonging to the group. When q is an odd number greater than 2, the median value of the q current values is the ((q/2)+0.5)th largest current value among the q current values. When q is an even number equal to or greater than 2, the median value of the q current values is the (q/2)th largest current value (or the ((q/2)+1)th largest current value). When there are two or more current values in a single group, the maximum value or minimum value of the two or more current values may be used as the representative value for the group.

The representative values of the first through fourth groups are IREP[1]˜IREP[4]. After establishing the representative values, IREP[1]˜IREP[4], the representative value IREP[1] of the first group is compared to the IREP[2]˜IREP[4] of the other groups to determine the degraded state of each battery module 1.

More specifically, when Equation (A4) below is satisfied, the determining unit 51 performs a specific degradation determination process on all of the battery modules 1 corresponding to the current values belonging to the ith group. When Equation (A4) below is not satisfied, it does not perform a specific degradation determination process on all of the battery modules 1 corresponding to the current values belonging to the ith group. In the determination process, 2, 3 and 4 can be substituted for i. For example, when i=4 and Equation (A4) is satisfied, the specific degradation determination process is not performed on the battery modules 1 corresponding to the current values in the second and third groups, that is, on battery modules 1[4] and 1[5]. Instead, it performs the specific degradation determination process on the battery modules 1 corresponding to the current values in the fourth group, that is, on battery modules 1[6]˜1[9].

|IREP[1]−IREP[i]|≧THA (A4)

The determining unit 51 does not perform the specific degradation determination on any of the battery modules 1 corresponding to the current values in the first group (that is, battery modules 1[1]˜1[3]), regardless of whether or not Equation (A4) is satisfied. This is because the battery modules 1 corresponding to the first group have a lower relative internal resistance value among the battery modules 1[1]˜1[9] and are thus believed to have a relatively low degree of degradation. The classification method for the current values IDET[1]˜IDET[9] is not limited to the one in this explanation. For example, the inequality equation “IDET[3]−IDET[4]>ΔεA” can be assumed rather than inequality equation “IDET[1]−IDET[4]>ΔεA”, and the classification can be performed on current values IDET[1]˜IDET[9] using clustering. The clustering can be performed using any clustering method common in the art. Some examples can be found in “Try Clustering! A Survey of Recent Clustering Methods for Data Mining (Part 1)” by Toshihiro Kamishima, the Journal of the Japanese Society for Artificial Intelligence, vol. 18, no. 1, pp. 59-65 (2003). Further explanation of these methods has been omitted here.

The results from the fifth example are similar to those in the second through fourth examples. In the examples of current values shown in FIG. 7, several battery modules 1[6]˜1[9] have degraded to a similar state. Therefore, when the methods in the second through fourth examples are applied to the current values in FIG. 7, the specific degradation determination is performed successively at different times on battery modules 1[9], 1[8], 1[7] and 1[6]. As a result, battery modules 1[9], 1[8], 1[7] and 1[6] have to be replaced on four different occasions. The fifth example can suppress the frequent replacement of battery modules because current values within range ΔεA are placed in a single group, and the degradation determination is performed on the group as a whole.

In the fifth example, IREP[1] and IREP[i] correspond to the first and second comparison amounts. When the difference between the first and second comparison amounts is greater than a predetermined value, the determining unit 51 performs a specific degradation determination on the one or more battery modules 1 corresponding to IREP[i]. When the difference between the first and second comparison amounts is less than a predetermined value, it does not perform a specific degradation determination on the one or more battery modules 1 corresponding to IREP[i]. As in the case of the first example, the size relationship between the difference in the first and second comparison amounts and the predetermined level can be evaluated using the ratio of the first and second comparison amounts. (This is also true in modified techniques α1 and α2 described below).

The following is an explanation of the first modified technique α1 for the fifth example. The internal resistance of batteries usually increases as the battery degrades. However, one factor in degradation is believed to be a reduction in the internal resistance of a battery as a battery degrades. Therefore, the modified technique α1 takes this into account by having the determining unit 51 determine whether or not current value IDET[i] satisfies Equation (A5) below. When Equation (A5) is satisfied, a specific degradation determination is performed on the battery module 1[i]. When Equation (A5) is not satisfied, the specific degradation determination is not performed on the battery module 1[i]. The determining unit 51 either performs or does not perform this specific degradation determination on each of the battery modules 1[1]˜1[9]. The inequality sign “≧” in Equation (A5) can also be “>”.

|IREF−IDET[i]|≧THA2 (A5)

The average value or median value of the current values IDET[1]˜IDET[9] can be used as the reference current value (statistical amount) IREF. Therefore, the specific degradation determination is performed in modified technique α1 on the battery modules 1 with current value far from the overall group. THA2 is a current value with a positive value. The current value THA2 can also be a predetermined fixed value. The kA multiple of the standard deviation of the current values IDET[1]˜IDET[9] can also be used as THA2 (where kA is a positive fixed value).

The following is an explanation of the second modified technique α2 of the fifth example. In this example, it is assumed that degraded battery modules 1 are specified when some of the battery modules 1 rapidly degrade for whatever reason relative to the other battery modules 1. In addition to this, the determining unit 51 in the modified technique α2 performs the degradation determination (whether or not to perform a specific degradation determination) on the battery modules 1[1]˜1[9] all at once. In other words, when a plurality of battery modules 1 degrades to a certain extent, there is a sharp divergence in the degree of degradation between the battery modules 1. Taking this into account, the determining unit 51 in modified technique α2 determines the variation in the current values IDET[1]˜IDET[9]. When the variation exceeds a predetermined reference value, it is determined that degradation has increased in the battery modules 1, and the specific degradation determination is performed on all of the battery modules 1[1]˜1[9]. When the variation does not exceed a predetermined reference value, the specific degradation determination is not performed on all of the battery modules 1[1]˜1[9]. The variation in the current values IDET[1]˜IDET[9] can be the standard deviation or distribution of the current values IDET[1]˜IDET[9].

### 6th Example

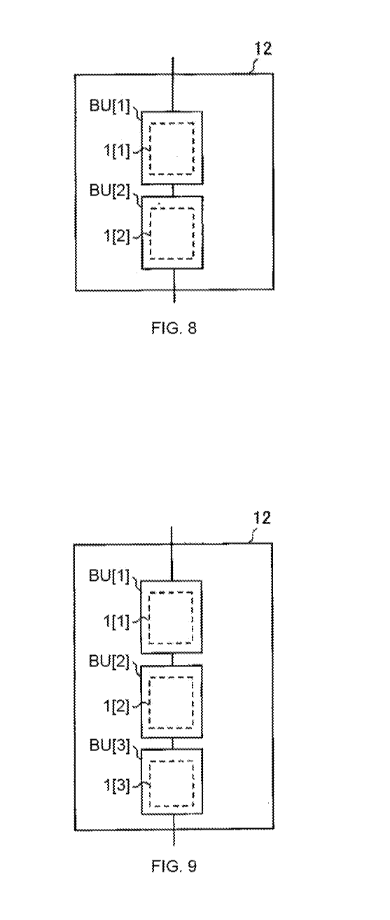

The following is an explanation of the sixth example. In the sixth example, as shown in FIG. 8, battery units BU[1] and BU[2] among battery units BU[1]˜BU[n] are connected to each other in series. As a result, battery module 1[1] and battery module 1[2] are assumed to be connected to each other in series.

When battery modules 1[1] and 1[2] are connected in series, the charge or discharge current of the battery modules 1[1] and 1[2] is the same. If the battery modules 1[1] and 1[2] have the same characteristics (including degradation state), the SOC of the battery modules 1[1] and 1[2] is the same, and the rate of change in the SOC of the battery modules 1[1] and 1[2] is the same when the battery modules 1[1] and 1[2] are charged or discharged. As a result, the rate of change in the voltage of the battery modules 1[1] and 1[2] is also the same when the battery modules 1[1] and 1[2] are charged or discharged.

However, when the degree of degradation of battery module 1[2] is greater than battery module 1[1], the full charge capacity of battery module 1[2] is lower than that of the first battery module 1[1], and the rate of change in the SOC of battery module 1[2] is greater than that of battery module 1[1] when battery modules 1[1] and 1[2] are charged or discharged. As a result, the rate of change in the output voltage of battery module 1[2] is greater than that of battery module 1[1] when battery modules 1[1] and 1[2] are charged or discharged.

Taking this into account, the determining unit 51 determines the degradation state of battery modules 1[1] and 1[2] by comparing the rate of change VCR[1] in the output voltage of battery module 1[1] to the rate of change VCR [2] in the output voltage of battery module 1[2]. The determining unit 51 can acquire the measured voltage value VDET[i] on a first and second timing while the battery module [1] is being charged or discharged, determine the absolute value of the difference VDFF[i] in the measured voltage values VDET[i] on the first and second timings, and divide the absolute value VDFF [i] by the difference ΔT between the first and second timing to determine the rate of change VCR [i] in the output voltage of the battery module 1[i] (that is, VCR [i]=VDFF [i]/AT). The determining unit 51 can determine the rate of change VCR [i] for each battery module 1 in this way. The rates of change to be compared can, of course, be measured on the same timing.

When Equation (B1) below is satisfied, the determining unit 51 performs the specific degradation determination on either battery module 1[1] or 1[2]. When Equation (B1) below is not satisfied, it performs the specific degradation determination on neither battery module 1[1] nor 1[2]. When the determining unit 51 performs the specific degradation determination on either battery module 1[1] or 1[2], it performs the specific degradation determination on battery module 1[2] if inequality equation “VCR [1]<VCR [2]” is satisfied, and performs the specific degradation determination on battery module 1[1] if inequality equation “VCR [1]>VCR [2]” is satisfied. In Equation (B1) and in Equations (B2), (B3) and (B4) described later, the inequality symbol “≧” can be “>” instead.

|VCR[1]−VCR[2]|≧THB (B1)

THB is a specific rate of change with a positive value. Rate-of-change THB can be a predetermined fixed value, or can be a variable that changes depending on the SOC, measured voltage value VDET, or temperature of the battery modules 1[1] and 1[2].

In this example, by introducing a simple comparison process, the degraded state of a battery module can be easily determined during normal operation of the battery system in which the battery module 1 is charging or discharging electricity.

In the sixth example, VCR [1] and VCR [2] correspond to first and second comparison amounts. When the difference between the first and second comparison amounts is greater than a predetermined level, the determining unit 51 performs a specific degradation determination on either battery module 1[1] or battery module 1[2]. When the difference between the first and second comparison amounts is less than a predetermined level, the determining unit 51 performs a specific degradation determination on neither battery module 1[1] nor battery module 1[2]. The size relationship between the difference in the first and second comparison amounts and the predetermined level may be evaluated using a ratio of the first and second comparison amounts. (The same is true in the seventh through tenth examples described below.) When the ratio of the first and second comparison amounts falls outside of a predetermined numerical range, the difference between the first and second comparison amounts is greater than the predetermined level. When the ratio of the first to second comparison amounts is within the predetermined numerical range, the difference between the first and second comparison amounts is less than the predetermined level. (The same is true in the seventh through tenth examples described below.) The numerical range is the numerical range from predetermined threshold value THU to predetermined threshold value THL, where THU>1>THL>0. If the larger of the two physical amounts corresponding to the first and second comparison amounts (VCR [1] and VCR [2] in the sixth example) is the first comparison amount, the ratio of the first comparison amount to the second comparison amount (that is, 1st comparison amount/2nd comparison amount) is compared to threshold value THU. When the ratio is greater than THU, a specific degradation determination is performed on the battery module 1 corresponding to the second comparison amount.

### 7th Example

The following is an explanation of the seventh example. In the seventh example, as shown in FIG. 9, battery units BU[1] and BU[3] among battery units BU[1]˜BU[n] are connected to each other in series. As a result, battery module 1[1] through battery module 1[3] are assumed to be connected to each other in series. When three battery modules 1 are connected in series, the degradation state can be determined using the method described in the sixth example.

In other words, by comparing the rate of change VCR [1]˜VCR [3] in the output voltage of battery modules 1[1]˜1[3], the determining unit 51 determines the degradation state of battery modules 1[1]˜1[3].

More specifically, the determining unit 51 first extracts the minimum rate-of-change value and a non-minimum rate-of-change value, or rate-of-change value other than the minimum rate-of-change value, from the rates of change VCR [1]˜VCR [3]. Here, the minimum rate-of-change value is represented by the symbol VCR [MIN], and the two non-minimum rate-of-change values are represented by the symbols VCR [NOTMIN1] and VCR [NOTMIN2].

The determining unit 51 treats rate-of-change values VCR [MIN] and VCR [NOTMIN1] as VCR [1] and VCR [2] in the sixth example, and performs the same determination process as that in the sixth example. It also treats rate-of-change values VCR [MIN] and VCR [NOTMIN2] as VCR [1] and VCR [2] in the sixth example, and performs the same determination process as that in the sixth example. In other words, the determining unit 51 performs a specific degradation determination on the battery module 1 corresponding to rate-of-change value VCR [NOTMIN1] when Equation (B2) below is satisfied, and does not perform the specific degradation determination on the battery module 1 corresponding to rate-of-change value VCR [NOTMIN1] when Equation (B2) below is not satisfied. Similarly, the determining unit 51 performs a specific degradation determination on the battery module 1 corresponding to rate-of-change value VCR [NOTMIN2] when Equation (B3) below is satisfied, and does not perform the specific degradation determination on the battery module 1 corresponding to rate-of-change value VCR [NOTMIN2] when Equation (B3) below is not satisfied. When rate-of-change value VCR [NOTMIN1] is rate-of-change value VCR [i], the battery module 1 corresponding to rate-of-change value VCR [NOTMIN1] is battery module [i]. (The same is true of rate-of-change values VCR [MIN] and VCR [NOTMIN2]).

|VCR[MIN]−VCR[NOTMIN1]|≧THB (B2)

|VCR[MIN]−VCR[NOTMIN2]|≧THB (B3)

The determining unit 51 does not perform the specific degradation determination on the battery module corresponding to rate-of-change value VCR [MIN], regardless of whether Equations (B2) and (B3) are satisfied. The battery module 1 corresponding to current value VCR [MIN] has the highest full charge capacity of battery modules 1[1]˜1[3] and is thus considered to have the lowest degree of degradation.

Results similar to those in the sixth example are obtained in the seventh example. In the seventh example, the degradation state of another battery module 1 can be determined on the assumption that the battery module 1 corresponding to rate-of-change value VCR [MIN] is a battery module with no degradation or a very low level of degradation.

In the seventh example, VCR [MIN] and VCR [NOTMIN1] correspond to the first and second comparison amounts, and VCR [MIN] and VCR [NOTMIN2] also correspond to the first and second comparison amounts. When the difference between the first and second comparison amounts is greater than a predetermined level, the determining unit 51 performs a specific degradation determination on the battery module 1 corresponding to VCR [NOTMIN1] or VCR [NOTMIN2]. When the difference between the first and second comparison amounts is less than a predetermined level, the determining unit 51 does not perform a specific degradation determination on the battery module 1 corresponding to VCR [NOTMIN1] or VCR [NOTMIN2]. As in the sixth example, the size relationship between the difference in the first and second comparison amounts and the predetermined level is evaluated using the ratio of the first and second comparison amounts.

In the seventh example, the degradation state determining process was performed on three battery modules 1 connected in series. However, the same process can also be performed when four or more battery modules 1 are connected in series.

### 8th Example

The following is an explanation of the eighth example. In the seventh example, a non-minimum rate-of-change value was compared to a reference rate-of-change value, the reference rate-of-change value being the extracted minimum rate-of-change value. However, the reference rate-of-change value compared to the non-minimum rate-of-change value can be generated from a plurality of rate-of-change values including the minimum rate-of-change value.

The following is a specific example. Here, battery units BU[1]˜BU[m] among battery units BU[1]˜BU[n] are connected in series. Therefore, it is assumed that battery modules 1[1]˜1[m] are also connected in series. Here, m is any integer less than n and equal to or greater than 3. In this explanation, m=4.

The determining unit 51 determines the degraded state of each battery module by comparing rate-of-change values VCR [1]˜VCR [4] measured on the same timing. At this time, the rate-of-change values VCR [1]˜VCR [4] are classified as being in a first group or a second group. The rate-of-change values classified as being in the first group (that is, the rate-of-change values belonging to the first group) are all greater than the rate-of-change values classified as being in the second groups (that is, rate-of-change values belonging to the second group). Therefore, the minimum rate-of-change value among rate-of-change values VCR [1]˜VCR [4] is classified as being in the first group. More specifically, the rate-of-change values whose difference with respect to the minimum rate-of-change value among rate-of-change values VCR [1]˜VCR [4] is less than a predetermined positive value are extracted from rate-of-change values VCR [1]˜VCR [4] and classified as being in the first group. The rest of the rate-of-change values are classified as being in the second group.

The determining unit 51 establishes the reference rate-of-change value VCR [MIN] using the rate-of-change values belonging to the first group. When the only rate-of-change value belonging to the first group is the minimum rate-of-change value itself, the minimum rate-of-change value is used as reference rate-of-change value VCR [MIN′]. When there is more than one rate-of-change value belonging to the first group, the average value of the rate-of-change values belonging to the first group is used as the reference rate-of-change value VCR [MIN′]. After the reference rate-of-change value VCR [MIN′] has been established, the determining unit 51 can treat VCR [MIN′] in the same way as VCR [MIN] in the seventh example, and perform the determination process in the same manner as the seventh example.

For example, when rate-of-change values VCR [1] and VCR [2] belong to the first group and rate-of-change values VCR [3] and VCR [4] belong to the second group, the determining unit 51 uses VCR [1] and VCR [2] to establish VCR [MIN], treats VCR [3] and VCR [4] as VCR [NOTMIN1] and VCR [NOTMIN2], and performs the process in the same manner as the seventh example using VCR [MIN′] as VCR [MIN] from the seventh example. As in the case of the first group, a single rate-of-change value may belong to the second group.

The specific degradation determination is not performed on a battery module 1 corresponding to a rate-of-change value belonging to the first group. This is because any battery module 1 in the first group is assumed to have a relatively low degree of degradation. The results in the eighth example are similar to those in the sixth example. In the eighth example, the degradation state of other battery modules 1 can be determined on the assumption that the battery modules 1 in the first group are reference battery modules 1 with either no degradation or very little degradation.

### 9th Example

The following is an explanation of the ninth example. Here, battery units BU[1]˜BU[m] among battery units BU[1]˜BU[n] are connected in series. Therefore, it is assumed that battery modules 1[1]˜1[m] are also connected in series. (Here, m is an integer equal to or greater than 3.)

In this example, the determining unit 51 determines the degradation state of each combination of two battery modules 1[i] and 1[j] among the battery modules 1[1]˜1[m]. Here, i and j in battery modules 1[i] and 1[j] are different integers.

In this particular example, m=3. First, the determining unit 51 establishes the combination of battery modules 1[1] and 1[2] as the combination whose degradation states are to be determined, and determines the degradation states of the battery modules 1[1] and 1[2] by comparing the rate-of-change values VCR [1] and VCR [2]. This method of determination matches the one in the sixth example. Second, the determining unit 51 establishes the combination of battery modules 1[2] and 1[3] as the combination whose degradation states are to be determined, and determines the degradation states of the battery modules 1[2] and 1[3] by comparing the rate-of-change values VCR [2] and VCR [3]. This method of determination is also the same as the one in the sixth example (except that 1[1], 1[2], VCR [1] and VCR [2] in the sixth example are replaced by 1[2], 1[3], VCR [2] and VCR [3]). Third, the determining unit 51 establishes the combination of battery modules 1[3] and 1[1] as the combination whose degradation states are to be determined, and determines the degradation states of the battery modules 1[3] and 1[1] by comparing the rate-of-change values VCR [3] and VCR [1]. This method of determination is also the same as the one in the sixth example (except that 1[1], 1[2], VCR [1] and VCR [2] in the sixth example are replaced by 1[3], 1[1], VCR [3] and VCR [1]).

In the ninth example, the degradation state determination is performed on combinations of two battery modules using a comparison of rate-of-change values. Here, the minimum rate-of-change value does not have to be explicitly extracted. The operations and effects of the seventh example can be obtained by comparing the rate-of-change values in any combination as the minimum rate-of-change value and non-minimum rate-of-change value. However, when a large number of battery modules 1 are connected in series, establishing a reference rate-of-change value (VCR [MIN] or VCR [MIN′]) as in the seventh or eighth example is preferred as it reduces the computational load.

### 10th Example

The following is an explanation of the tenth example. Here, battery units BU[1]˜BU[m] among battery units BU[1]˜BU[n] are connected in series. Therefore, it is assumed that battery modules 1[1]˜1[m] are also connected in series. Here, m is any integer less than n and equal to or greater than 3. In this explanation, m=9.

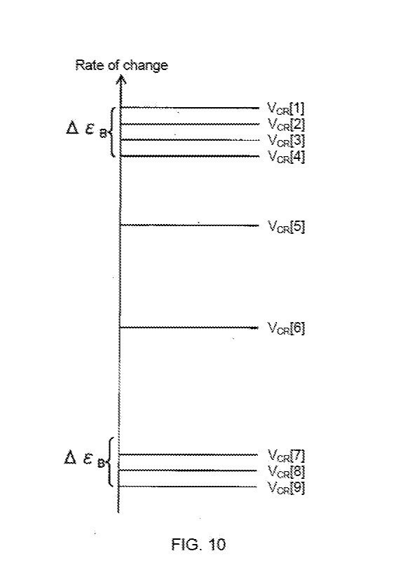

The determining unit 51 classifies rate-of-change values VCR [1]˜VCR [9] measured on the same timing into a plurality of groups. At this time, the determining unit 51 classifies the rate-of-change values VCR [1]˜VCR [9] so that rate-of-change values within the same range of a predetermined size ΔεB are within the same group (ΔεB>0). Here, it is assumed, as shown in FIG. 10, that inequality equation “VCR [1]>VCR [2]>VCR [3]>VCR [4]>VCR [5]>VCR [6]>VCR [7]>VCR [8]>VCR [9]” has been established, and that that inequality equations “VCR [1]−VCR [3]<ΔεB”, “VCR [1]−VCR [4]>ΔεB”, “VCR [4]−VCR [5]>ΔεB”, “VCR [5]−VCR [6]>ΔεB” and “VCR [6]−VCR [9]<ΔεB” have also been established. Also, for any integer i, the rate-of-change values belonging to the ith group are greater than the rate-of-change values belonging to the (i+1)th group. Therefore, rate-of-change values VCR [1]˜VCR [3] are classified as being in the 1st group, rate-of-change value VCR [4] is classified as being in the 2nd group, rate-of-change value VCR [5] is classified as being in the 3rd group, and rate-of-change values VCR [6]˜VCR [9] are classified as being in the 4th group.

After classifying the rate-of-change values in the first through fourth groups, the determining unit 51 establishes representative values (statistical amounts) for each group. When a group includes only a single value, the representative value is the rate-of-change value belonging to the group. Therefore, the representative values for the second and third groups are, respectively, rate-of-change values VCR [4] and VCR [5]. When there are two or more rate-of-change values in a single group, the representative value for the group can be the average value, median value, minimum value or minimum value of the two or more rate-of-change values belonging to the group. When q is an odd number greater than 2, the median value of the q rate-of-change values is the ((q/2)+0.5)th largest rate-of-change value among the q rate-of-change values. When q is an even number equal to or greater than 2, the median value of the q rate-of-change values is the (q/2)th largest rate-of-change value (or the ((q/2)+1)th largest rate-of-change value). When there are two or more rate-of-change values in a single group, the minimum value or minimum value of the two or more rate-of-change values may be used as the representative value for the group.

The representative values of the first through fourth groups are VREP[1]˜VREP [4]. After establishing the representative values, VREP [1]˜VREP [4], the determining unit 51 compares the representative value VREP [1] of the first group to the VREP [2]˜VREP [4] of the other groups to determine the degraded state of each battery module 1.

More specifically, when Equation (B4) below is satisfied, the determining unit 51 performs a specific degradation determination process on all of the battery modules 1 corresponding to the rate-of-change values belonging to the ith group. When Equation (B4) below is not satisfied, it does not perform a specific degradation determination process on all of the battery modules 1 corresponding to the rate-of-change values belonging to the ith group. In the determination process, 2, 3 and 4 can be substituted for i. For example, when i=4 and Equation (B4) is satisfied, the specific degradation determination process is not performed on the battery modules 1 corresponding to the rate-of-change values in the second and third groups, that is, on battery modules 1[4] and 1[5]. Instead, it performs the specific degradation determination process on the battery modules 1 corresponding to the rate-of-change values in the fourth group, that is, on battery modules 1[6]˜1[9].

|VREP[1]−VREP[i]|≧THB (B4)

The determining unit 51 does not perform the specific degradation determination on any of the battery modules 1 corresponding to the rate-of-change values in the first group (that is, battery modules 1[1]˜1[3]), regardless of whether or not Equation (B4) is satisfied. This is because the battery modules 1 corresponding to the first group have a higher relative full charge capacity among the battery modules 1[1]˜1[9] and are thus believed to have a relatively low degree of degradation. The classification method for the rate-of-change values VCR [1]˜VCR [9] is not limited to the one in this explanation. For example, the inequality equation “VCR [3]−VCR [4]>ΔεB” can be assumed rather than inequality equation “VCR [1]−VCR [4]>ΔεB”, and the classification can be performed on rate-of-change values VCR [1]˜VCR [9] using clustering.

The results from the tenth example are similar to those in the seventh through ninth examples. In the examples of rate-of-change values shown in FIG. 10, several battery modules 1[6]˜1[9] have degraded to a similar state. Therefore, when the methods in the seventh through ninth examples are applied to the rate-of-change values in FIG. 10, the specific degradation determination is performed successively at different times on battery modules 1[9], 1[8], 1[7] and 1[6]. As a result, battery modules 1[9], 1[8], 1[7] and 1[6] have to be replaced on four different occasions. The tenth example can suppress the frequent replacement of battery modules because rate-of-change values within range ΔεB are placed in a single group, and the degradation determination is performed on the group as a whole.

In the tenth example, VREP [1] and VREP [i] correspond to the first and second comparison amounts. When the difference between the first and second comparison amounts is greater than a predetermined value, the determining unit 51 performs a specific degradation determination on the one or more battery modules 1 corresponding to VREP [i]. When the difference between the first and second comparison amounts is less than a predetermined value, it does not perform a specific degradation determination on the one or more battery modules 1 corresponding to VREP [i]. As in the case of the sixth example, the size relationship between the difference in the first and second comparison amounts and the predetermined level can be evaluated using the ratio of the first and second comparison amounts. (This is also true in modified techniques β1 and β2 described below).

The following is an explanation of the first modified technique β1 for the tenth example. As in the case of modified technique α1 in the fifth example, in modified technique β1, the determining unit 51 determines whether or not rate-of-change value VCR [i] satisfies Equation (B5) below. When Equation (B5) is satisfied, a specific degradation determination is performed on the battery module 1[i]. When Equation (B5) is not satisfied, the specific degradation determination is not performed on the battery module 1[i]. The determining unit 51 either performs or does not perform this specific degradation determination on each of the battery modules 1[1]˜1[9]. The inequality sign “≧” in Equation (B5) can also be “>”.

|VREF−VCR[i]|≧THB2 (B5)

The average value or median value of the rate-of-change values VCR [1]˜VCR [9] can be used as the reference rate-of-change value (statistical amount) VREF. Therefore, the specific degradation determination is performed in modified technique β1 on the battery modules 1 with rate-of-change value far from the overall group. THB2 is a rate-of-change value with a positive value. The rate-of-change value THB2 can also be a predetermined fixed value. The kB multiple of the standard deviation of the rate-of-change values VCR [1]˜VCR [9] can also be used as THB2 (where kB is a positive fixed value).

The following is an explanation of the second modified technique 132 of the tenth example. As in the modified technique α2 of the fifth example, the determining unit 51 performs the degradation determination (whether or not to perform a specific degradation determination) on the battery modules 1[1]˜1[9] all at once. In other words, the determining unit 51 in modified technique 132 determines the variation in the rate-of-change values VCR [1]˜VCR [9]. When the variation exceeds a predetermined reference value, it is determined that degradation has increased in the battery modules 1, and the specific degradation determination is performed on all of the battery modules 1[1]˜1[9]. When the variation does not exceed a predetermined reference value, the specific degradation determination is not performed on all of the battery modules 1[1]˜1[9]. The variation in the rate-of-change values VCR [1]˜ VCR [9] can be the standard deviation or distribution of the rate-of-change values VCR [1]˜VCR [9].

### Variations

Several variations of the embodiments of the present invention are possible without departing from the technical scope of the claims. The embodiments described above are examples of embodiments of the present invention, and the meanings of the terms for each configurational requirement of the present invention are not restricted to the descriptions in the embodiments above. Specific numerical values in the text of the descriptions are merely for illustrative purposes, and these can be changed to any other numerical value. Annotations applicable to the embodiments described above are included below in Note 1 through Note 3. The contents of these notes can be combined in any way that is not contradictory.

### [Note 1]

Some or all of the battery system shown in FIG. 2 can be mounted in another type of system or device. For example, a battery system including a main control unit 11, battery block 12, switching circuit 13, breaker 14 and storage unit 15 can be mounted in a mobile object operated using power discharged from the battery block 12 (an electric vehicle, boat, aircraft, elevator, walking robot, etc.) or in an electronic device (personal computer, mobile phone, etc.), or can be incorporated into a power system for a household or production facility.

### [Note 2]

The main control unit 11 or the determining unit 51 can be configured of hardware, or a combination of hardware and software. The functions realized using software may be stored in a program, and the program executed by a program-executing device (such as a computer) to perform the functions.

### [Note 3]

In the embodiments described above, the determining unit 51 determines the degradation state of a battery module 1[i] in two stages, that is, by performing or not performing a specific degradation determination on the battery module 1[i]. In this two-stage process, one stage (the state in which the specific degradation determination is not performed) corresponds to a battery module 1[i] that has not degraded, and the other stage (the state in which the specific degradation determination is performed) corresponds to a battery module 1[i] that has degraded. In other words, by performing or not performing a specific degradation determination on the battery module 1[i], the determining unit 51 determines whether or not a battery module 1[i] has degraded.

### KEY TO THE DRAWINGS

BU: Battery unit
1: Battery module
2: Voltage measuring device
3: Current measuring device
11: Main control unit
12: Battery block
13: Switching circuit
51: Battery degraded state determining unit

What is claimed is:

1. A battery degradation determining device for a plurality of battery modules each having one or more secondary batteries, the battery degradation determining device characterized in that:
the plurality of battery modules are connected in parallel to each other; and the battery degradation determining device determines whether or not each battery module has degraded by comparing the charge or discharge current values of the plurality of battery modules.

2. The battery degradation determining device of claim 1, wherein the plurality of battery modules includes a first and second battery module, and the battery degradation determining device determines whether the first and second battery modules have degraded by comparing a first current value to a second current value, the first current value being the charge or discharge current value of the first battery module, and the second current value being the charge or discharge current value of the second battery module.

3. The battery degradation determining device of claim 2, wherein the battery degradation determining device determines that the second battery module has degraded when the difference between the first and second current values is greater than a predetermined value and the second current value is smaller than the first current value.

4. The battery degradation determining device of claim 1, wherein the plurality of battery modules includes a 1st through mth battery module (where m is an integer equal to or greater than 3), and the battery degradation determining device determines whether or not each battery module has degraded by extracting the highest current value and the other (m−1) non-highest current values from the 1st through mth current values, the current values being the charge or discharge current values of the 1st through mth battery modules, and by comparing the highest current value to each non-highest current value.

5. The battery degradation determining device of claim 1, wherein the plurality of battery modules includes a 1st through mth battery module (where m is an integer equal to or greater than 3), and the battery degradation determining device determines whether or not each battery module has degraded by classifying one or more current values of the 1st through mth current values within a predetermined first range in a first group, by classifying one or more current values within a predetermined second range in a second group, the current values being the charge or discharge current values of the 1st through mth battery modules, by eliminating any overlap between the first and second ranges, and by comparing statistics based on the current values belonging to the first group to statistics based on the current values belonging to the second group.

6. A battery degradation determining device for a plurality of battery modules each having one or more secondary batteries, the battery degradation determining device characterized in that:
the plurality of battery modules are connected in series to each other; and the battery degradation determining device determines whether or not each battery module has degraded by comparing the rate of change in the output voltage of the plurality of battery modules when the battery modules are charged or discharged.

7. The battery degradation determining device of claim 6, wherein the plurality of battery modules includes a first and second battery module, and the battery degradation determining device determines whether the first and second battery modules have degraded by comparing a first rate-of-change value to a second rate-of-change value, the first rate-of-change value being the rate of change in the output voltage of the first battery module, and the second rate-of-change value being the rate of change in the output voltage of the second battery module.

8. The battery degradation determining device of claim 7, wherein the battery degradation determining device determines that the second battery module has degraded when the difference between the first and second rate-of-change values is greater than a predetermined value and the second rate-of-change value is smaller than the first rate-of-change value.

9. The battery degradation determining device of claim 6, wherein the plurality of battery modules includes a 1st through mth battery module (where m is an integer equal to or greater than 3), and the battery degradation determining device determines whether or not each battery module has degraded by extracting the lowest rate-of-change value and the other (m−1) non-lowest rate-of-change values from the 1st through mth rate-of-change values, the rate-of-change values being the rate-of-change values for the output voltage of the 1st through mth battery modules, and by comparing the lowest rate-of-change value to each non-lowest rate-of-change value.

10. The battery degradation determining device of claim 6, wherein the plurality of battery modules includes a 1st through mth battery module (where m is an integer equal to or greater than 3), and the battery degradation determining device determines whether or not each battery module has degraded by classifying one or more rate-of-change values of the 1st through mth rate-of-change values within a predetermined first range in a first group, by classifying one or more rate-of-change values within a predetermined second range in a second group, the rate-of-change values being the rate-of-change values for the output voltage of the 1st through mth battery modules, by eliminating any overlap between the first and second ranges, and by comparing statistics based on the rate-of-change values belonging to the first group to statistics based on the rate-of-change values belonging to the second group.
